(19) United States
(12) Patent Application Publication
(10) Pub. No.: US 2019/0031502 A1
(43) Pub. Date: Jan. 31, 2019

(54) SEAL RING FOR AL-Ge BONDING

(71) Applicant: AGENCY FOR SCIENCE, TECHNOLOGY AND RESEARCH, Singapore (SG)

(72) Inventors: Vivek CHIDAMBARAM, Singapore (SG); Li Yan SIOW, Singapore (SG); Qing Xin ZHANG, Singapore (SG); Sunil WICKRAMANAYAKA, Singapore (SG)

(21) Appl. No.: 16/071,899

(22) PCT Filed: Jan. 26, 2017
(86) PCT No.: PCT/SG2017/050038

§ 371 Date: Jul. 20, 2018

(30) Foreign Application Priority Data
Feb. 11, 2016 (SG) 10201601013Y

(51) Int. Cl. B81C 1/00

(52) U.S. Cl. CPC B81C 1/00269; B81C 2203/0118; B81C 2203/019; B81C 2203/037

(57) ABSTRACT

There is provided a method of bonding a first substrate and a second substrate, the method comprising: providing an aluminium (Al) connection having a first width on one side of a first substrate; providing a germanium (Ge) connection having a second width on one side of a second substrate, wherein the second width is larger than the first width; and bonding the Al connection on the first substrate and the Ge connection on the second substrate by eutectic bonding of at least a portion of the Al connection and at least a portion of the Ge connection to form an Al—Ge eutectic melt, wherein the Al—Ge eutectic melt is confined within the second width of the Ge connection.

### FIELD OF THE INVENTION

The present invention relates to the field of CMOS compatible hermetic and vacuum packaging platform. In particular, it relates to aluminium-germanium (Al—Ge) wafer level bonding.

### BACKGROUND

Micro-electronic-mechanical systems (MEMS) require a controlled environment for better performance and hence needs to be hermetically sealed. Hermetic seals are also required to protect the MEMS devices from back-end operations such as dicing and sawing. Wafer level MEMS bonding, and in particular, aluminium-germanium (Al—Ge) wafer level bonding is gaining momentum in large volume foundries due to the potential of higher yield, better alignment accuracy, lower costs and complementary metal oxide semiconductor (CMOS) material compatibility.

Al—Ge bonding typically involves two stages: diffusion bonding across the bond interface to attain eutectic composition and subsequent eutectic melting and solidification. However, Al—Ge wafer level bonding is challenging when compared to commonly used transient-liquid phase bonding such as silver-tin (Ag—Sn) or copper-tin (Cu—Sn) due to high bonding temperatures requirements and stable oxide formation property of Al. High bonding temperatures are particularly a concern due to the non-uniformity in the bonding temperatures within a 200 mm wafer for a commercial wafer bonder. The temperature non-uniformity is less than or equal to 8° C. at a typical Al—Ge bonding temperature range of 428° C. to 450° C.

Splashing of the molten eutectic melt is a common phenomenon encountered in Al—Ge bonding. Splashing typically occurs during the initial phase of the Al—Ge bonding due to non-uniform temperature ramp rate in wafer level bonding. Splashing leads to the generation of massive voids at the interface, and results in poor hermeticity and lower bonding strength. Splashing of the eutectic melt may also result in shorting of pads/devices and hence hinders the miniaturisation of MEMS devices.

Accordingly, what is needed is a method of bonding a first substrate and a second substrate that seeks to address some of the above problems. Furthermore, other desirable features and characteristics will become apparent from the subsequent detailed description and the appended claims, taken in conjunction with the accompanying drawings and this background of the disclosure.

### SUMMARY OF INVENTION

In accordance with a first aspect of an embodiment, there is provided a method of bonding a first substrate and a second substrate, the method comprising: providing an aluminium (Al) connection having a first width on one side of a first substrate; providing a germanium (Ge) connection having a second width on one side of a second substrate, wherein the second width is larger than the first width; and bonding the Al connection on the first substrate and the Ge connection on the second substrate by eutectic bonding of at least a portion of the Al connection and at least a portion of the Ge connection to form an Al—Ge eutectic melt, wherein the Al—Ge eutectic melt is confined within the second width of the Ge connection.

In accordance with a second aspect of an embodiment, there is provided a substrate package comprising: a first substrate comprising an aluminium (Al) connection having a first width on one side of a first substrate; a second substrate comprising a germanium (Ge) connection having a second width on one side of a second substrate, wherein the second width is larger than the first width; and wherein the Al connection on the first substrate is bonded to the Ge connection on the second substrate such that at least a portion of the Al connection and at least a portion of the Ge connection forms a Al—Ge eutectic melt, and wherein the Al—Ge eutectic melt is confined within the second width of the Ge connection.

### BRIEF DESCRIPTION OF DRAWINGS

The accompanying figures, serve to illustrate various embodiments and to explain various principles and advantages in accordance with a present embodiment.

FIG. 1 illustrates a conventional structure for stacking Al/Ge for bonding purpose.

FIG. 2 illustrates splashing of the Al—Ge eutectic melt as a result of conventional structure of FIG. 1.

FIG. 3 illustrates a structure for stacking Al/Ge for bonding purpose in accordance with present application.

FIG. 4 illustrates Al—Ge eutectic melt as a result of structure of FIG. 3 in accordance with present application.

FIG. 5 illustrates a flow chart for method of bonding in accordance with present application.

FIG. 6A to 6C illustrate benchmarking of the larger width Al seal ring placed on stand-off for bonding purpose in a conventional manner.

FIG. 7A to 7C illustrate benchmarking of larger width Ge seal ring placed on stand-off for bonding purpose in accordance with present application.

FIGS. 8A and 8B illustrate splashing mitigation by adapting Ge>Al seal ring width in accordance with present application.

Skilled artisans will appreciate that elements in the figures are illustrated for simplicity and clarity and have not necessarily been depicted to scale. For example, the dimensions of some of the elements in the block diagrams or flowcharts may be exaggerated in respect of other elements to help to improve understanding of the present embodiments.

### DETAILED DESCRIPTION

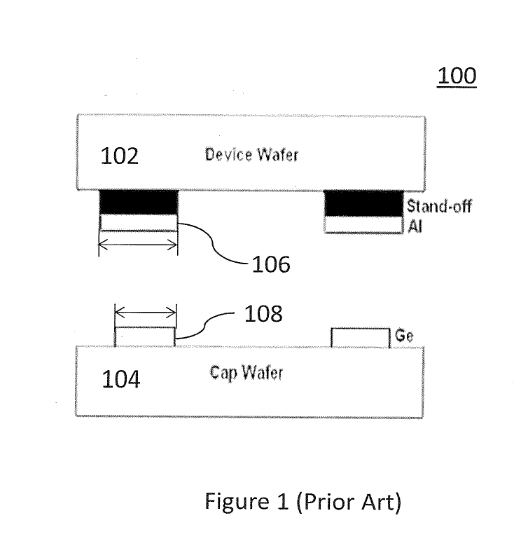

FIG. 1 illustrates a conventional structure 100 for stacking Al/Ge for bonding purpose. The width of the Al seal ring 106 deposited in the MEMS wafer (device wafer) 102 is a larger than the width of Ge seal ring 108 patterned on the cap/TSI wafer (cap wafer) 104. The purpose of designing larger seal ring width for Al when compared to Ge in conventional structures is to compensate for the process induced/hardware induced misalignment, which is typically about 5 μm. Al seal rings may or may not be placed on a stand-off. The stand-off may be created using native SiO₂ deposited by PECVD approach or formed on Si itself.

There are several drawbacks for this conventional approach. In particular, splashing is very serious. As a result of splashing of the eutectic melt, hermeticity is dramatically affected and bonding strength is significantly reduced. Shorting of bonding pads/devices is also major concern.

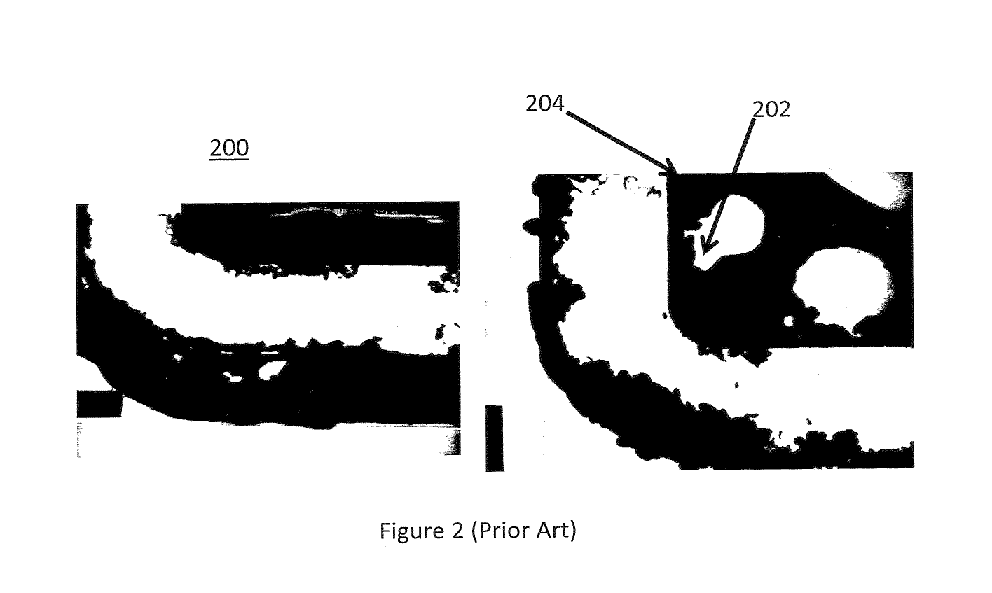

FIG. 2 illustrates splashing of the Al—Ge eutectic melt as a result of conventional approach of FIG. 1. The white region 202 on the seal ring captured by IR imaging indicates massive voids as a result of severe splashing. The black region 204 of the seal ring represents the molten metal which has been squeezed out of the seal ring pattern. In this case, a very large clearance between the device/contact pads from the seal ring is required to avert a short circuit.

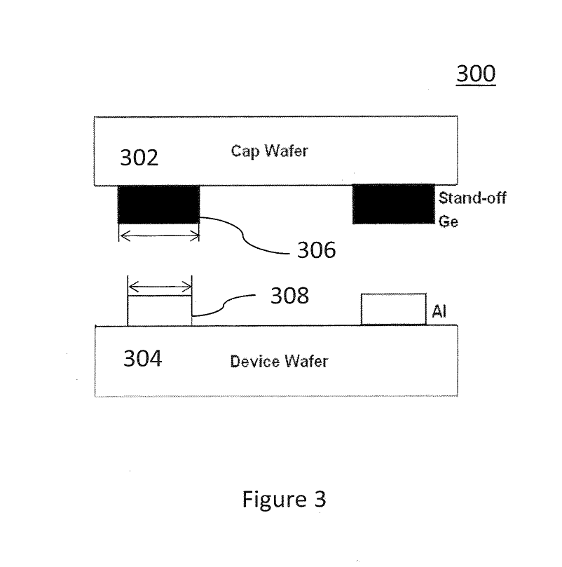

FIG. 3 illustrates an exemplary structure 300 of a substrate package for stacking Al/Ge for bonding purpose in accordance with present application. The structure includes

a first substrate 304 comprising an aluminium (Al) connection 308 having a first width on one side of a first substrate 304, and

a second substrate 302 comprising a germanium (Ge) connection 306 having a second width on one side of a second substrate 302.

The second width is larger than the first width. In an example, the second width is at least 1.1 times larger than the first width. In another example, the second width is up to 1.4 times larger than the first width. The second width is between 20 μm to 200 μm.

The Al connection 308 on the first substrate 304 is bonded to the Ge connection 306 on the second substrate 302 such that at least a portion of the Al connection 308 and at least a portion of the Ge connection 306 form a Al—Ge eutectic melt. In accordance with the present embodiment, the Al—Ge eutectic melt is advantageously confined within the second width of the Ge connection. In an example, the Al—Ge eutectic melt forms a hermetic seal ring and the hermetic seal ring includes a global seal ring, a device guard ring or a bond pad ring.

In an example, the first substrate 304 includes at least one MEMS device. In another example, the first substrate 304 includes a silicon wafer or a glass wafer. In an example, the second substrate 302 includes at least one stand-off extending from one side of the second substrate 302 and the Ge connection 306 is provided on the at least one stand-off. The at least one stand-off includes a material selected from a group including silicon, glass and any metallic or non-metallic oxides/nitrides. The second substrate 302 may include a silicon wafer or a glass wafer.

In an example, the structure 300 includes a larger Ge width seal ring 306 patterned in the cap/TSI wafer (cap wafer) 302. The Ge is placed on the stand-off. The stand-off can be an oxide or Si stand-off. The width of the Ge seal ring 306 should be larger than the Al seal ring 308 patterned on the MEMS wafer (device wafer) 304. The larger Ge width seal ring 306 can also be directly patterned on Si, glass, non-metallic oxides or diffusion barriers.

In accordance with the present embodiment, a width of the Ge seal ring 306 is larger (e.g. up to 1.4 times) than the Al seal ring width 308 to advantageous compensate process misalignment/splashing. Larger seal ring widths of Ge will ensure minimal splashing while bonding. Thereby, the sealing in accordance with the present embodiment enhances the bonding strength. Accordingly, larger seal ring widths of Ge when compared to Al will advantageously help to compensate process induced misalignment without compromising the bond strength.

In an example, the viscosity of the eutectic Al—Ge melt is higher in the unreacted Ge exposed area. The larger seal ring width of the Ge (Ge>Al) ensures that the squeeze of the eutectic melt is still within the bonding area. After solidification, the squeezed Al—Ge eutectic melt is still part of the joint. Hence, there will be no deterioration or less deterioration in the bonding strength. In addition, yield loss due to shorting of pads/devices is significantly reduced by minimizing the splashing.

Thus, varying seal ring width in accordance with present application, in addition of serving as a tolerance to misalignment, also significantly controls the splashing of the Al—Ge eutectic melt. Higher shear strength and hermeticity is, achieved since the splashing is completely controlled. Detail of higher shear strength and hermeticity is discussed in later together with Table 1 and Table 2.

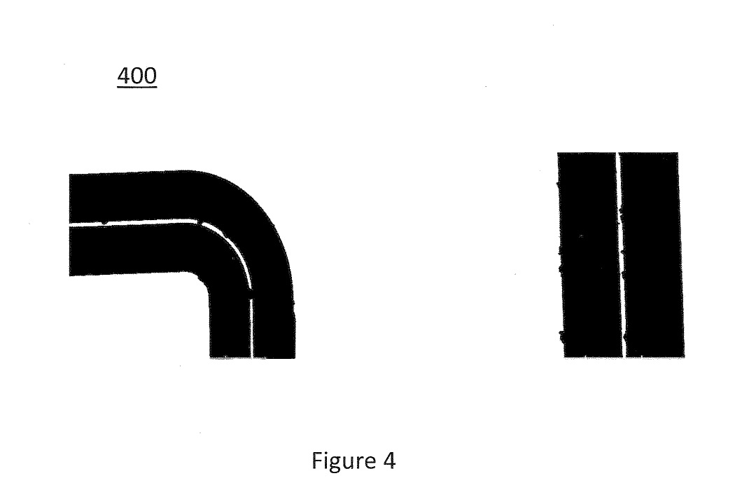

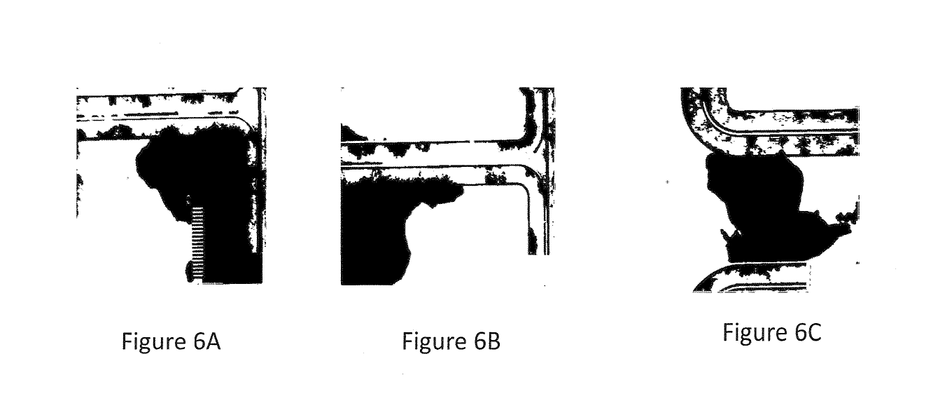

FIG. 4 illustrates Al—Ge eutectic melt 400 as a result of structure of FIG. 3 in accordance with present application. Comparison of FIG. 4 with FIG. 2 reveals that the larger Ge seal ring width (Ge>Al) ensures that there is no splashing or significant less splashing that is shown in FIG. 2. As a result, no voids could be observed. Accordingly, almost no clearance between the device/contact pads from the seal ring is required to avert a short circuit. Further comparison is discussed in the performance benchmarking part together with FIGS. 6 to 8.

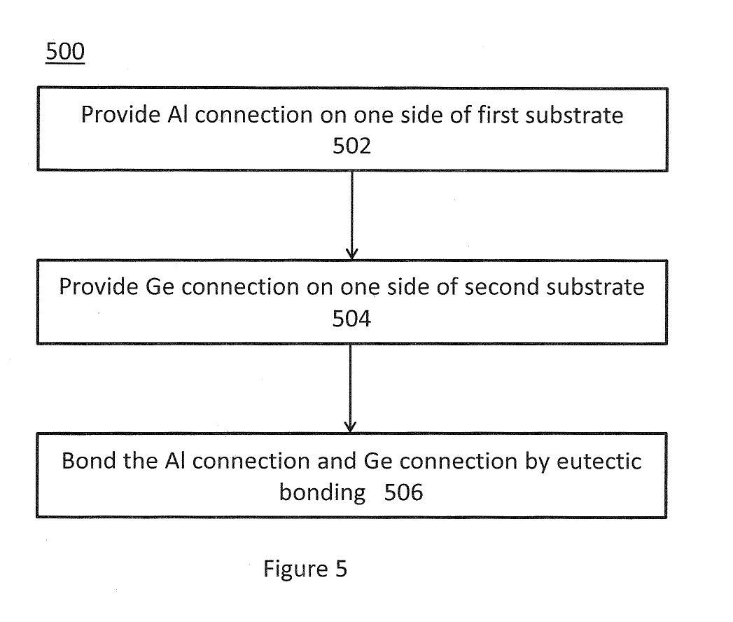

FIG. 5 illustrates a flow chart 500 for method of bonding in accordance with present application. The method broadly comprises:

Step 502: providing an aluminium (Al) connection having a first width on one side of a first substrate;

Step 504: providing a germanium (Ge) connection having a second width on one side of a second substrate, wherein the second width is larger than the first width; and

Step 506: bonding the Al connection on the first substrate and the Ge connection on the second substrate by eutectic bonding of at least a portion of the Al connection and at least a portion of the Ge connection to form an Al—Ge eutectic melt.

Step 502 involves providing an aluminium (Al) connection having a first width on one side of a first substrate. The first substrate may include at least one MEMS device. Alternatively, the first substrate may include a silicon wafer or a glass wafer.

Step 504 involves providing a germanium (Ge) connection having a second width on one side of a second substrate. The second substrate may include a silicon wafer or a glass wafer. The step of providing a Ge connection may include providing the Ge connection on at least one stand-off extending from one side of the second substrate. The at least one stand-off may include a material selected from a group comprising silicon, glass and any metallic or non-metallic oxides/nitrides.

Step 506 involves bonding the Al connection on the first substrate and the Ge connection on the second substrate by eutectic bonding of at least a portion of the Al connection and at least a portion of the Ge connection to form an Al—Ge eutectic melt. The Al—Ge eutectic melt is confined within the second width of the Ge connection.

In an example, the second width is larger than the first width by a factor sufficient to significantly reduce splashing of the Al—Ge eutectic melt during the bonding stage. The factor may be up to 1.4 times. Also, the factor may be at least 1.1 times. In an example, the second width is between 20 μm to 200 μm.

In an example, the step of bonding may include contacting the Al connection with the Ge connection, and heating the Al connection and the Ge connection to an Al—Ge eutectic temperature. In an example, the Al—Ge eutectic temperature is between 428° C. to 450° C.

### Performance Benchmarking

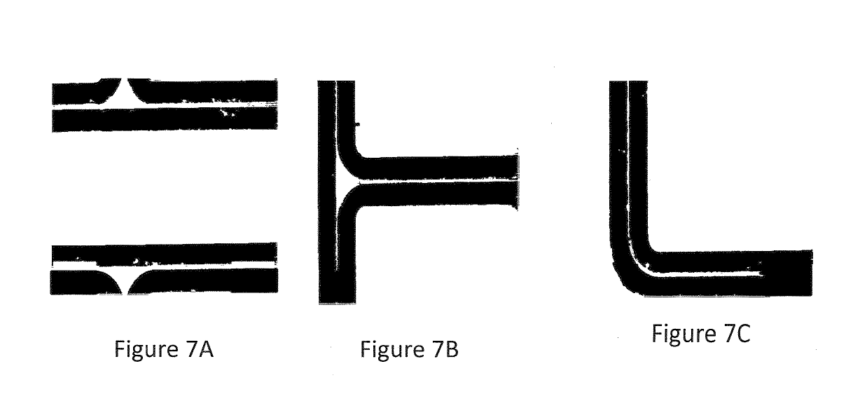

FIGS. 6 and 7 illustrate benchmarking between a larger width Al seal ring placed on a stand-off for bonding purpose (FIGS. 6A, 6B, 6C) and a larger width Ge seal ring placed on the stand-off for bonding purpose (FIGS. 7A, 7B, 7C) for validating the structure of the present application. Characterization of the bonding was done by IR imaging. IR images from the Ge side can capture the magnitude of the eutectic reaction, magnitude of splashing, presence of voids in the interface, misalignment, etc. The white regions in the seal indicate the presence of voids. Large white patches on the seal ring indicate massive voids as a result of splashing. Small white spots on the seal ring indicate bonding voids as a result of Kirkendall porosities.

FIGS. 6A to 6C illustrate exemplary post-bonding IR images of conventional Al>Ge seal ring width. Post-bonding IR images clearly confirm that the exposed Al area will result in excessive squeezing and, thereby, result in shorting of pads/devices. In the worst case of the conventional Al>Ge seal ring width, the magnitude of splashing can be up to 200 μm. Bonding strength and hermeticity is therefore dramatically reduced.

As shown in FIGS. 6A to 6C, massive void formations are found at the interface as a result of splashing of eutectic melt, when a larger seal ring width of Al is placed on a stand-off for bonding. The white patches on the seal ring indicate massive voiding while the dark region indicates squeeze out melt which may result in shorting of devices/pads.

FIGS. 7A to 7C illustrate an exemplary post-bonding IR images of Ge>Al seal ring width in accordance with the present application. The large Ge width seal ring (Ge>Al) mitigates splashing. Only bonding voids were observed at the interface as shown in FIGS. 7A to 7C. A significant difference in the bond quality is observed by placing a larger width Al (Al>Ge) on stand-off in a conventional manner versus placing a larger width Ge (Ge>Al) on the stand-off in accordance with present application.

As shown in FIG. 7A to 7C, there is less or no squeezing of the eutectic melt and only bonding voids marked by white dots are formed at the interface, when a larger width of Ge is placed on the stand-off for bonding purpose.

The mechanism behind the experimental observation is that the viscosity of the Al—Ge eutectic melt is reduced in the Al exposed area whereas the viscosity of the eutectic melt is higher in the Ge exposed area. Thus, it has been proven that the structure for the Al—Ge eutectic bonding in accordance with present application mitigates splashing. Thus, the serious concern for wafer level Al—Ge eutectic bonding is addressed by the structure and method of present application.

### Splashing Elimination

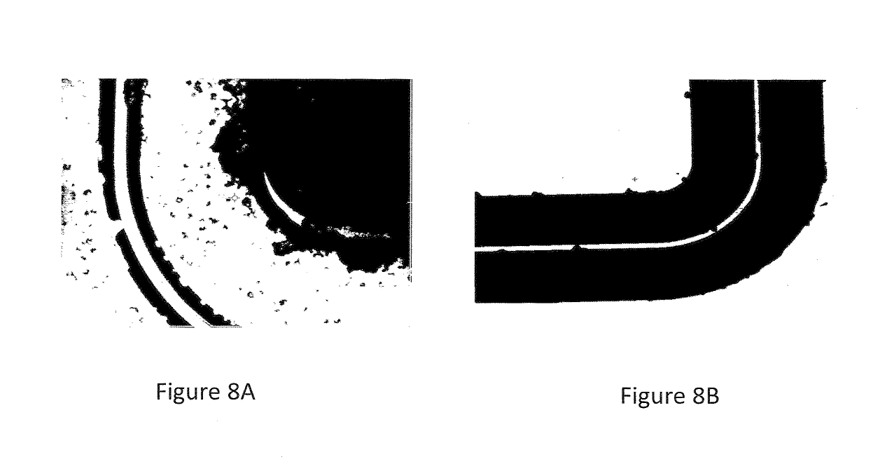

FIGS. 8A and 8B illustrate splashing mitigation by adapting the Ge/Al seal ring width. Splashing of the Al—Ge eutectic melt which could be in the range of 5 μm to 200 μm could be effectively controlled by adapting the Ge>Al seal ring width. As shown in FIG. 8A, the Al>Ge seal ring width results in massive splashing. The black regions outside the seal ring represent splashing, while the white patches on the seal ring indicate massive voiding.

On the other hand, as shown in FIG. 8B, the black seal ring without any white patches or dots indicates a hermetic seal ring. Thus, it is evident that hermetic Al—Ge seal ring without any splashing can be achieved by adapting a larger Ge seal ring width when compared to Al. Moreover, shorting of bonding pads and devices can be avoided by this approach and thus, facilitates the drive for miniaturization.

### Shear Strength and Hermeticity Testing

Shear strength and hermeticity for the Ge>Al seal ring width and the Al>Ge seal ring width has also been tested. The results of shear strength are discussed with reference to Table 1. The results of hermeticity are discussed with reference to Table 2. In short, the Ge>Al width results are stable, while the Al>Ge widths are fluctuating due to varying magnitude of metal squeeze out.

Table 1 shows the impact of Al>Ge vs Ge>Al seal ring widths on shear strength. According to Table 1, a larger Ge seal ring width results in significant higher shear strength. Shear strength values are consistent for all Ge>Al seal ring width because no splashing is encountered. On the other hand, conventional Al>Ge seal ring widths result in lower shear strength. The shear strength values are also inconsistent due to massive splashing.

There is a good correlation between the magnitude of splashing and shear strength. Generally, dies possess lower shear strength when the magnitude of the splashing is higher.

TABLE 1
Impact of “Al > Ge” vs “Ge > Al” seal ring width on shear strength

| | Shear Strength (MPa) | |
|---|---|---|
| Sample | Al on Stand-off (Prior art) | Ge on stand-off |
| Number | “Al > Ge” seal ring width | “Ge > Al” seal ring width |
| 1 | 13 | 48 |
| 2 | 28 | 55 |
| 3 | 14 | 50 |
| 4 | 24 | 53 |
| 5 | 17 | 53 |

Table 2 shows the impact of “Al>Ge” vs “Ge>Al” seal ring widths on hermeticity. According to Table 2, larger Ge seal ring width results in better hermeticity. Hermeticity was determined using helium leak rate testing. Hermeticity values are consistent for all Ge>Al seal ring width because almost no splashing is encountered. However, the conventional Al>Ge seal ring widths result in poor hermeticity.

There is good correlation between hermeticity and splashing of the eutectic melt. Based on the specific volume, the sealant is considered to be hermetic, according to MIL-STD-883, if the leakage rate is less than 5×10⁸ atm cc/sec. The Ge>Al seal ring widths result in samples which are in compliance with military standards and always pass the hermeticity leak tests, while majority of the AL>Ge seal ring width samples are incompliant with the Military standards. Some of the samples bonded by latter approach are found to be open, with the cross-section results indicating massive splashing.

TABLE 2
Impact of “Al > Ge” vs “Ge > Al” seal ring width on hermeticity

| | Hermeticity (MPa) | |
|---|---|---|
| Sample | Al on Stand-off | Ge on stand-off |
| Number | “Al > Ge” seal ring width | “Ge > Al” seal ring width |
| 1 | 4.7 × 10⁻⁵ | 0.4 × 10⁻⁹ |
| 2 | 9.2 × 10⁻⁷ | 5.3 × 10⁻⁹ |
| 3 | 2.4 × 10⁻⁵ | 0.2 × 10⁻⁹ |
| 4 | 7.9 × 10⁻⁶ | 3.1 × 10⁻⁹ |
| 5 | 8.1 × 10⁻⁴ | 2.2 × 10⁻⁹ |

### CONCLUSION

By implementing the methods and the structures in accordance with present embodiment, splashing of the eutectic melt is controlled. Also, shorting of pads/devices due to splashing is avoided by the method and the structure. The structure advantageously improves hermeticity and bonding strength. This facilitates the drive for miniaturization and, thereby cost reduction, since spacing between the seal ring and the devices/pads can be reduced. Also, implementation of the methods and the structures in accordance with present embodiment into practice will not result in any additional cost or efforts. Only slight modification in design rules is required. In addition, it has been proven that the linked seal ring concept is more reliable than the global seal ring.

Furthermore, by improving hermeticity, the methods and structures in accordance with the present embodiment will facilitate high-temperature degassing to ensure complete outgassing of inert gases like Argon (Ar) and Helium (He), which is advantageous in industrial applications.

It should further be appreciated that the exemplary embodiments are only examples, and are not intended to limit the scope, applicability, operation, or configuration of the invention in any way. Rather, the foregoing detailed description will provide those skilled in the art with a convenient road map for implementing an exemplary embodiment of the invention, it being understood that various changes may be made in the function and arrangement of elements and method of operation described in an exemplary embodiment without departing from the scope of the invention as set forth in the appended claims.

1. A method of bonding a first substrate and a second substrate by a Al—Ge bond, the method comprising:
providing an aluminium (Al) connection having a first width on one side of a first substrate;
providing a germanium (Ge) connection having a second width on one side of a second substrate, wherein the second width of the Ge connection is larger than the first width of the Al connection by a factor of at least 1.1 times and wherein geranium is only deposited on the Ge connection; and
bonding the Al connection on the first substrate and the Ge connection on the second substrate by eutectic bonding of at least a portion of the Al connection and at least a portion of the Ge connection to form an Al—Ge eutectic melt, wherein the Al—Ge eutectic melt is confined within the second width of the Ge connection in response to the Ge connection being larger than the first width of the Al connection by a factor of at least 1.1 times thereby significantly reducing splashing of the Al—Ge eutectic melt and ensuring high shear strength and hermeticity of the Al—Ge bond.

2. The method as claimed in claim 1, wherein the step of bonding comprises:
contacting the Al connection with the Ge connection; and
heating the Al connection and the Ge connection to an Al—Ge eutectic temperature.

3. The method as claimed in claim 2, wherein the Al—Ge eutectic temperature is between 428° C. to 450° C.

4. (canceled)

5. The method as claimed in claim 1, wherein the factor is up to 1.4 times.

6. (canceled)

7. The method as claimed in claim 1, wherein the second width is between 20 μm to 200 μm.

8. The method as claimed in claim 1, wherein the step of providing the Ge connection comprises providing the Ge connection on at least one stand-off extending from one side of the second substrate.

9. The method as claimed in claim 8, wherein the at least one stand-off comprises a material selected from a group comprising silicon, glass and any metallic or non-metallic oxides/nitrides.

10. The method as claimed in claim 1, wherein the first substrate comprises at least one MEMS device.

11. The method as claimed in claim 1, wherein the first substrate comprises a silicon wafer or a glass wafer.

12. The method as claimed in claim 1, wherein the second substrate comprises a silicon wafer or a glass wafer.

13. A substrate package comprising:
a first substrate comprising an aluminium (Al) connection having a first width on one side of a first substrate;
a second substrate comprising a germanium (Ge) connection having a second width on one side of a second substrate, wherein the second width of the Ge connection is larger than the first width of the Al connection by a factor of at least 1.1 times and up to 1.4 times; and wherein the Al connection on the first substrate is bonded to the Ge connection on the second substrate such that at least a portion of the Al connection and at least a portion of the Ge connection forms a Al—Ge eutectic melt, and wherein the Al—Ge eutectic melt is confined within the second width of the Ge connection in response to the Ge connection being larger than the first width of the Al connection by a factor of at least 1.1 times and up to 1.4 times thereby significantly reducing splashing of the Al—Ge eutectic melt and ensuring that the Al—Ge bond forms a hermetic seal ring with high shear strength.

14. (canceled)

15. The substrate package as claimed in claim 13, wherein the hermetic seal ring comprises a global seal ring, a device guard ring or a bond pad ring.

16. (canceled)

17. (canceled)

18. The substrate package as claimed in claim 13, wherein the second width is between 20 μm to 200 μm.

19. The substrate package as claimed in claim 13, wherein the second substrate comprises at least one stand-off extending from one side of the second substrate, the Ge connection provided on the at least one stand-off.

20. The substrate package as claimed in claim 19, wherein the at least one stand-off comprises a material selected from a group comprising silicon, glass and any metallic or non-metallic oxides/nitrides.

21. The substrate package as claimed in claim 13, wherein the first substrate comprises at least one MEMS device.

22. The substrate package as claimed in claim 13, wherein the first substrate comprises a silicon wafer or a glass wafer.

23. The substrate package as claimed in claim 13, wherein the second substrate comprises a silicon wafer or a glass wafer.
